(19) United States
(12) Patent Application Publication
(10) Pub. No.: US 2009/0017303 A1
(43) Pub. Date: Jan. 15, 2009

(54) ZINC OXIDE HAVING ENHANCED PHOTOCATALYTIC ACTIVITY

(75) Inventors: Jin Ho CHOY, Seoul (KR); Tae Un Park, Seoul (KR); Eue Soon Jang, Daejeon (KR)

Correspondence Address: SUGHRUE MION, PLLC, 2100 PENNSYLVANIA AVENUE, N.W., SUITE 800, WASHINGTON, DC, 20037, US

(73) Assignee: FAS Alliances, Inc., Seoul (KR)

(21) Appl. No.: 12/138,399

(22) Filed: Jun. 12, 2008

Related U.S. Application Data
(60) Provisional application No. 60/943,414, filed on Jun. 12, 2007.

(51) Int. Cl. C01G 9/02; C30B 7/14; B32B 5/16

(52) U.S. Cl. 428/402; 117/68; 423/622

(57) ABSTRACT

The present invention relates to a method for increasing a photocatalytic activity of zinc oxide, which comprises preparing zinc oxide nanoplate crystals having a planar morphology on their (0001) crystal faces. In addition, the present invention relates to a process for synthesizing zinc oxide nanoplate crystals, a tooth whitening composition and a composition for degrading organic pollutants.

### CROSS-REFERENCE TO RELATED APPLICATIONS

This application claims priority from the U.S. Provision Application 60/943,414, filed on Jun. 12, 2007 in the USPTO, the disclosure of which is incorporated herein by reference.

### BACKGROUND OF THE INVENTION

1. Field of the Invention

The present invention relates to a method for increasing a photocatalytic activity of zinc oxide. In addition, the present invention relates to a process for synthesizing zinc oxide nanoplate crystals, a tooth whitening composition and a composition for degrading organic pollutants.

2. Description of the Related Art

Photocatalytic reactions have plausible advantages to degrade environmental pollutants. The surface of natural-occurring ceramics or inorganic particles is considered interface where photocatalytic reactions occur, emitting electrons upon ultraviolet irradiation to accelerate degradation of pollutants. Zinc oxide and titanium oxide are representative of inorganic materials having photocatalytic activity. Of them, zinc oxide has been widely utilized because it is significantly accessible and one of essential nutrients to human.

The most prominent feature of photocatalytic inorganic materials is that their atoms are readily changed from ground state to excited state upon ultraviolet irradiation. Excited electrons and electron holes generated during excitation are involved in chemical reactions to increase reaction rates. If the reactions are to degrade pollutants, natural purification is greatly accelerated.

Due to the fact that a photocatalytic reaction occurs at the interface between catalyst surfaces and pollutants, the surface characteristics of photocatalysts are extremely pivotal. Therefore, various approaches to increase photocatalytic efficiency have been suggested: for example, preparation of photocatalysts by use of composite materials rather than single material; surface modification by coating; and increase in specific surface area of photocatalysts.

Because ZnO is well known to exhibit much less photocatalytic efficiency, it has been likely not to serve as photocatalysts to induce chemical reactions due to their excitation capacity but to serve as UV-screening cosmetics due to its UV absorbing capacity.

Hydrogen peroxide has been long utilized for tooth whitening. It is permissible as OTC (over the counter) products in the United States but not in the Europe. According to SCCP/0844/04 (Scientific Committee on Consumer Product: Opinion on Hydrogen Peroxide in Tooth Whitening Products) issued in 2005, the concentrations of hydrogen peroxide at less than 0.1% are suggested safe but those from 0.1% to 6% requires dentist prescription, making the use of hydrogen peroxide greatly restricted.

Throughout this application, various patents and publications are referenced and citations are provided in parentheses. The disclosure of these patents and publications in their entities are hereby incorporated by references into this application in order to more fully describe this invention and the state of the art to which this invention pertains.

### SUMMARY OF THE INVENTION

The present inventors have made intensive researches to overcome shortcomings associated with conventional zinc oxide particles with restricted applicability (e.g., UV screening agents) due to their lower photocatalytic activities although their safety to human is excellent. The inventors have diminished the sizes of conventional zinc oxide particles to nanometer scale for increasing their surface area as well as increasing ratios of crystal faces with higher catalytic activities, thereby providing ZnO nanoplates with much higher photocatalytic activities than conventional zinc oxide particles. The ZnO nanoplates of this invention have hydrogen peroxide-generating activities sufficient to whiten teeth and degrade organic pollutants.

Accordingly, it is an object of this invention to provide a method for increasing a photocatalytic activity of zinc oxide.

It is another object of this invention to provide a process for synthesizing zinc oxide nanoplate crystals with enhanced photocatalytic activity.

It is still another object of this invention to provide a novel application of zinc oxide nanoplate crystals with enhanced photocatalytic activity to tooth whitening.

It is further object of this invention to provide a novel application of zinc oxide nanoplate crystals with enhanced photocatalytic activity to degradation of organic pollutants.

Other objects and advantages of the present invention will become apparent from the following detailed description together with the appended claims and drawings.

### BRIEF DESCRIPTION OF THE DRAWINGS

FIG. 1 represents a TEM (transmission electron microscopy) image of global-shaped ZnO nanoparticles with an average diameter of 4 nm prepared by one embodiment of this invention.

FIG. 2 represents FESEM (field-emission scanning electron microscopy) images of (a) nanorods, (b) nanoplates, (c) microrods, and (d) dumbbell-shaped microrods of zinc oxide.

FIG. 3 is FESEM image of ZnO nanoplates demonstrating that the size of ZnO nanoplates may be varied depending on synthesis conditions.

FIG. 4 represents time profiles of the evolution of H₂O₂ in UV-illuminated (wavelength λ>300 nm) suspensions of (a) nanoplates, (b) nanorods, (c) microrods and (d) dumbbell-shaped microrods of zinc oxide. The profiles represent the weight-normalized data.

FIG. 5 represents time profiles of the evolution of H₂O₂ in UV-illuminated (wavelength λ>300 nm) suspensions of (a) nanoplates and (b) nanorods. The profiles represent the surface-area-normalized data.

### DETAILED DESCRIPTION OF THIS INVENTION

In one aspect of this invention, there is provided a method for increasing a photocatalytic activity of zinc oxide, which comprises preparing zinc oxide nanoplate crystals having a planar morphology on their (0001) crystal faces.

In another aspect of this invention, there is provided a process for synthesizing zinc oxide nanoplate crystals having a planar morphology on their (0001) crystal faces, which comprises inducing a crystal growth of zinc oxide nanoparticles acting as crystal nuclei in a zinc oxide crystal growth solution containing a metal citrate salt.

In still another aspect of this invention, there is provided a tooth whitening composition, which comprises an effective amount of zinc oxide nanoplate crystals having a planar morphology on their (0001) crystal faces.

In further aspect of this invention, there is provided a composition for degrading organic pollutants, which comprises an effective amount of zinc oxide nanoplate crystals having a planar morphology on their (0001) crystal faces.

In still further aspect of this invention, there is provided a method for tooth whitening, which comprises administering to a subject an effective amount of a tooth whitening composition comprising zinc oxide nanoplate crystals having a planar morphology on their (0001) crystal faces.

In another aspect of this invention, there is provided a method for degrading organic pollutants, which comprises contacting an effective amount of zinc oxide nanoplate crystals having a planar morphology on their (0001) crystal faces to the organic pollutants.

The present invention will be described in more detail as follows:

The photocatalytic activity of ZnO is strongly dependent on the growth direction of the crystal plane. The present inventors have first discovered that (0001) faces perpendicular to c-axis contribute greatly to photocatalytic activity of zinc oxide. Based on the discovery, the present inventors have prepared planar ZnO nanoparticles with maximized (0001) faces and increased surface area, i.e., nanoplates and elucidated their photocatalytic activity is significantly enhanced.

Due to an intrinsic anisotropy in the growth rate v of ZnO, with v [0001]>>v [011 0]>v [0001 ], hexagonal rods elongated along the c-axis have been predominantly synthesized. Such an anisotropic tendency in crystal growth makes it difficult to directly probe the relationship between face orientation and photocatalytic activity. Here we report the novel face-tunable synthesis of ZnO crystals with different ratios of polar to nonpolar faces. With these morphology-controlled crystals, we are able to clearly demonstrate a strong dependence of photocatalytic activity on a specific crystal plane.

According to a preferred embodiment, the zinc oxide nanoplate crystals have an average thickness of less than 100 nm and an aspect ratio of more than 20 in considering photocatalytic activity of zinc oxide. More preferably, the zinc oxide nanoplate crystals have an average thickness of 100-30 nm, still more preferably, 80-40 nm, most preferably 60-40 nm. More preferably, the zinc oxide nanoplate crystals have the aspect ratio of 20-40, most preferably, 20-30.

According to a preferred embodiment, the zinc oxide nanoplate crystals have the (0001) face area of more than 2 m²g⁻¹, more preferably, 2-5 m²g⁻¹, most preferably 3-5 m²g⁻¹.

The present process for synthesizing zinc oxide nanoplate crystals having a planar morphology on their (0001) crystal faces, characterized in that it comprises inducing a crystal growth of zinc oxide nanoparticles acting as crystal nuclei in a zinc oxide crystal growth solution containing a metal citrate salt. The present process is considerably different from known process for synthesizing helical ZnO nanorods by use of metal citrate without ZnO nanoparticle crystal nuclei (Z. R. Tian et. al., J. Am. Chem. Soc., 2002, 124, 12954-12955). Therefore, the photocatalytic characteristics of the present ZnO nanoplates are considered to be greatly different from those of the conventional technologies.

According to the present process, the metal citrate salt in the zinc oxide crystal growth solution suppresses crystal growth of zinc oxide nanoparticles along the [0001] axis and promotes crystal growth along the [01-10] axis, finally giving ZnO nanoplate crystals with planar (0001) faces. Zn²⁺ ions of the Zn²⁺-terminated (0001) faces are complexed with citrate ligands originated from metal citrate salts, resulting in a strong suppression of crystal growth of zinc oxide nanoparticles along the [0001] axis with a relative enhancement of crystal growth along the [01-10] axis to produce nanoplate crystals with a larger population of (0001) faces.

According to a preferred embodiment, the induction of the crystal growth is carried out for more than 1 hr (more preferably 1-100 hr) at 30-400° C.

According to a preferred embodiment, the metal citrate salt enabling to suppress crystal growth of zinc oxide nanoparticles along the [0001] axis and promote crystal growth along the [01-10] axis is sodium citrate, ammonium citrate or their combination. Most preferably, the metal citrate salt is sodium citrate.

According to a preferred embodiment, the zinc oxide crystal growth solution comprises (i) a zinc salt selected from the group consisting of Zn(CH₃COO)₂.(H₂O)ₓ (x is an integer of 0-6), Zn(NO₃)₂.(H₂O)ₓ (x is an integer of 0-6), ZnX₂ (X is F, Cl, Br or I), zinc citrate(H₂O)ₓ (x is an integer of 0-6) and their combination, and (ii) a base selected from the group consisting of sodium hydroxide, lithium hydroxide and their combination. Most preferably, a mixed solution of Zn(CH₃COO)₂.(H₂O)ₓ and sodium hydroxide is used as the zinc oxide crystal growth solution.

The ZnO nanoplate crystals having a planar morphology on their (0001) crystal faces exhibit significantly enhanced photocatalytic activity to generate hydrogen peroxide in much higher levels upon UV irradiation, ensuring application to tooth whitening and degradation of organic pollutants.

The ZnO nanoplate crystals having a planar morphology on their (0001) crystal faces catalyze production of hydrogen peroxide by UV irradiation in much higher levels than ZnO particles having other morphology such as ZnO nanorods, microrods and dumbbell-shaped microrods. In this regard, the ZnO nanoplate crystals having a planar morphology on their (0001) crystal faces permit to generate hydrogen peroxide sufficient to whiten teeth.

Although hydrogen peroxide has been conventionally utilized for tooth whitening, its safety in high concentration becomes problematic. Using the ZnO nanoplate crystals having a planar morphology on their (0001) crystal faces, the generation of hydrogen peroxide can be localized at a UV-irradiated region. Therefore, the serious safety problem associated with direct use of hydrogen peroxide can be overcome.

The tooth whitening composition of this invention further may comprise hole scavengers including acetic acid and acetate salts for promoting generation of hydrogen peroxide.

The concentration of the ZnO nanoplate crystals in the tooth whitening composition may be varied, e.g., at less than about 30 M. The tooth whitening composition of this invention may be locally coated onto teeth and then UV light is irradiated at the coated teeth for whitening.

In addition, the zinc oxide nanoplate crystals having a planar morphology on their (0001) crystal faces are very effective in degrading organic pollutants due to their enhanced photocatalytic activity.

The present invention will now be described in further detail by examples. It would be obvious to those skilled in the art that these examples are intended to be more concretely illustrative and the scope of the present invention as set forth in the appended claims is not limited to or by the examples.

### EXAMPLES

Examples described herein illustrate one embodiment of this invention in which nanoparticles serving as crystal nuclei for ZnO nanoplates are first synthesized and then ZnO nanoplate crystals having planar (0001) plane. In addition, ZnO crystal particles having various crystal structures were synthesized and their photocatalytic activities were determined by evaluating hydrogen peroxide generation potentials for elucidating the fact that ZnO nanoplates of this invention have much higher photocatalytic activities than ZnO crystal particles having other morphologies.

### Example 1

### Synthesis of Zinc Oxide Nanoparticles

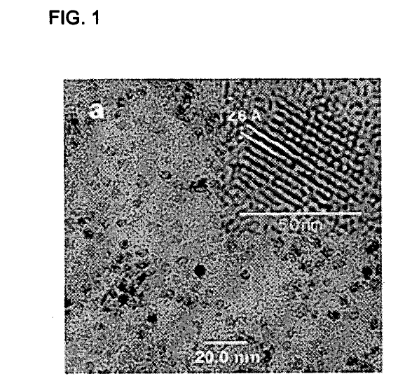

ZnO nanoparticles were prepared by synthesis of precursors using Zn acetate and ethanol (99.5%) and hydrolysis using LiOH. Specifically, 0.01 M Zn acetate in 100 mL ethanol was introduced into a 250 ml round bottom flask equipped with condenser and refluxed for 3 hr at 78-85° C. to the extent that the volume of the solution was reduced from 100 mL to 40 mL. The refluxing time was revealed important: where the period of time exceeds 3 hr. heterogeneous nanoparticles with large sizes were formed to generate unclear solution; in the case of less than 3 hr. precursors obtained were unlikely to act. The finally precursors should be clear and transparent. 40 ml precursor solution was diluted with 60 ml of 0.1 M LiOH in ethanol. At this time, the increase in temperatures of the solution is likely to lead to the increase in ZnO crystal sizes. Therefore, the solution was introduced into ice bath and ultrasonificated for 2 hr (120 W. 35 kHz). FIG. 1 shows images of transmission electron microscope (TEM) for ZnO nanoparticles finally obtained. The inlet in FIG. 1 is a magnified image of (a) portion of FIG. 1, representing the size of ZnO nanoparticles is about 4 nm. FIG. 1 represents HR-TEM images of ZnO nanoparticles. The distance between lattices was revealed about 5.2 Å in consistence with a typical c-axis length of Wurtzite ZnO nanoparticles. The homogeneity of ZnO nanoparticles as starting materials for nanoplates is significantly pivotal in synthesis of nanoplates with uniform sizes.

### Example 2

### Synthesis of Zinc Oxide Nanoplate Crystals

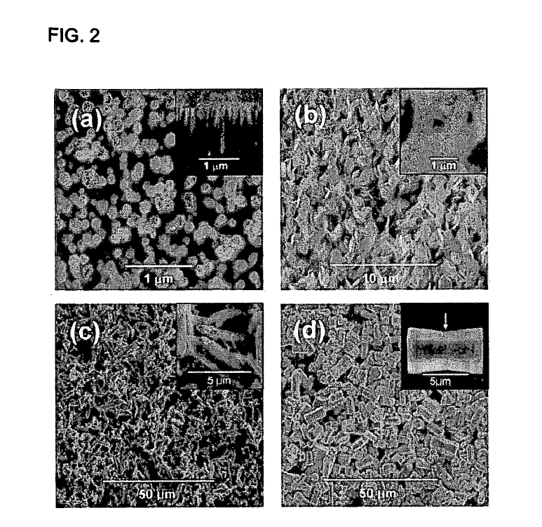

The nanoplates were synthesized from the nanoparticles obtained in Example 1 by a soft-solution process at 95° C. for 24 h under a nutrient solution (100 mL) of 0.5 M Zn(CH₃COO)₂.2H₂O, 0.1 M NaOH and 0.17 mM sodium citrate. The resultant was removed of unreacted reactants using deionized water and filtered to yield pure crystals with planar morphology. The panel (b) of FIG. 2 represents FESEM (field-emission scanning electron microscopy) image of ZnO nanoplates finally prepared.

As shown in the FESEM image, it was verified that planar nanoparticles having an average thickness of 50 nm and average diameter of 1 μm were prepared and planes-forming faces, i.e., (0001) faces are perpendicular to the c-axis of crystals.

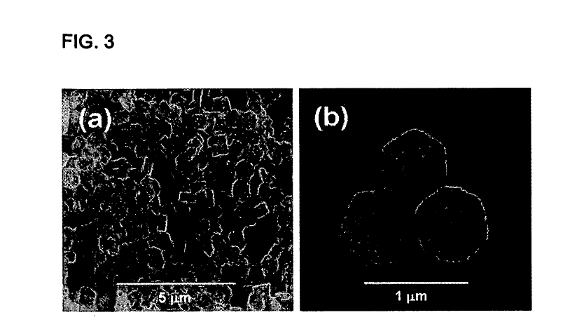

Alternatively, the nanoplates were synthesized from the nanoparticles obtained in Example 1 by a soft-solution process at 95° C. for 24 hr under a nutrient solution (100 mL) of 0.5 M Zn(CH₃COO)₂.2H₂O, 0.2 M NaOH and 0.1 mM sodium citrate. FIG. 3 represents FESEM image of ZnO nanoplates finally prepared. As shown in FIG. 3, it was elucidated that planar nanoparticles having an average thickness of 40 nm and average diameter of about 700 nm were prepared and planes-forming faces, demonstrating that the thickness of ZnO nanoplates is varied depending on concentrations of sodium citrate and sodium hydroxide.

### Comparative Example 1

### Synthesis of Zinc Oxide Nanorod Crystals

Silicon wafer (1 cm×1 cm) was washed in a sonicator using acetone and etched for 30 min at room temperature using a mixed solution (volume ratio 2:1) of concentrated sulfuric acid and 30% hydrogen peroxide. The etched silicon water was dipped into the dispersion of ZnO nanoparticles obtained in Example 1 and then taken out at rate of 4 cm/min for coating. The Si wafer coated with ZnO nanoparticles was immersed into a mixed nutrient solution containing 0.1 M zinc nitrate and 0.1 M hexamethylenetetramine (volume ratio 1:1) and underwent hydrothermal reaction in an autoclave for 6 hr at 95° C., followed by slow cooling to room temperature. The silicon wafer was washed several times by deionized water, each nanorod was separated from the substrate by scratching, and then dispersed into the deionized water by ultrasonification. The panel (a) of FIG. 2 shows FESEM image of nanorods finally prepared. The corresponding FESEM image of FIG. 2a reveals the formation of a dense array of ZnO nanorods with a uniform diameter of 100 nm and a length of 1.5 μm. Due to a one-dimensional nanostructure extended along the [0001] direction, the hexagonal ZnO nanorods have a larger population of nonpolar {011 0} faces than polar {0001} ones.

### Comparative Example 2

### Synthesis of Zinc Oxide Microrod Crystals

The microrods were hydrothermally synthesized from aqueous solution (100 mL) of 1.0 M Zn(CH₃COO)₂.2H₂O and 2.0 M NaOH at 200° C. for 12 hr. As represented in FIG. 2(c), the hydrothermal reaction of zinc acetate under basic conditions resulted in prismatic ZnO microrods. Due to an increase in particle size, the area of nonpolar {011 0} planes in this microrod was much reduced, compared with that of the nanorod.

### Comparative Example 3

### Synthesis of Dumbbell-Shaped Zinc Oxide Microrod Crystals

The dumbbell-shaped (DB) microrods were synthesized from the aqueous solution of 0.1 M Zn(CH₃COO)₂.2H₂O and 0.1 M hexamethylenetetramine (HMTA) under hydrothermal conditions of 95° C. for 6 hr. The crystal structure and crystallite morphology of the reaction intermediates in the synthesis of the DB crystals were studied by XRD, FESEM (JEOL JSM-6700F microscope), and HRTEM/SAED. The morphology of the microcrystals could be further tailored by use of acetate-intercalated zinc hydroxy double salt (Zn—HDS) as an intermediate (FIG. 2d). By carrying out FESEM, high-resolution transmission electron microscopy/selected-area electron diffraction (HRTEM/SAED), and X-ray diffraction (XRD) analyses on the reaction intermediates, it was determined that a fraction of the outermost surface of the Zn—HDS intermediate was transformed into hexagonal ZnO crystallites under hydrothermal conditions at 95° C. (the fraction depended on the pH variation of the nutrient solution), after which the surface-formed ZnO crystallites acted as nucleation centers for dumbbell-shaped ZnO microrods (hereafter referred to as DB microrods). Since the intercalated acetate anions in the Zn—HDS lattice were stabilized between the Zn (0001) planes through the formation of DB microrods, the Zn (0001) faces were completely masked. In fact, the FESEM image of FIG. 2d reveals that the DB microrods were formed by co-sharing the acetate ligands, giving rise to the hybridization of two individual microrod crystals. One thing to note here is that both hexagonal microrods and DB microrods turn out to have a broader size distribution than the nanorods and nanoplates.

The characteristics of zinc oxide crystals prepared in Example 2 and Comparative Examples 1-3 are summarized in Table 1.

TABLE 1

| | Average | Average | | Area of Zn |
|---|---|---|---|---|
| | diameter | thickness | Area of total | (0001) |
| | [μm] | [μm] | surface [m²g⁻¹] | face [m²g⁻¹] |
| Nanoplates | 1.00 | 0.05 | 7.70 | 3.53 |
| Nanorods | 0.10 | 1.50 | 8.30 | 0.12 |
| Microrods | 1.80 | 6.20 | 0.50 | 0.03 |
| DB microrods | 3.50 | 6.00 | 0.25 | — |

As indicated in Table 1, the total surface area of nanoplates is similar to that of nanorods, and the area of Zn (0001) face of nanoplates is about 120 times larger than that of microrods.

### EXPERIMENTAL EXAMPLE 1

### Measurement of Hydrogen Peroxide Generation by UV Irradiation

To study the photocatalytic generation of H₂O₂, a 0.01 g ZnO sample was put into a 200 mL quartz cell containing of 120 mL of 2 mM acetate solution as a hole scavenger, and then the resulting suspension was continuously stirred under UV irradiation (300 W Xe lamp) and oxygen bubbling (30 mL min⁻¹). The time evolution of H₂O₂ concentration was examined by an iodide method [A. J. Hoffmann, et al., Environ. Sci. Technol. 1994, 28, 776; E. R. Carraway, et al., Environ. Sci. Technol. 1994, 28, 786], whose detection limit was approximately 10⁻⁶ mol. The concentration of triiodide ions (I₃⁻) generated from four different stock solutions was determined from UV-vis absorption spectroscopy and the resulting standard calibration curve was used to estimate the H₂O₂ concentration.

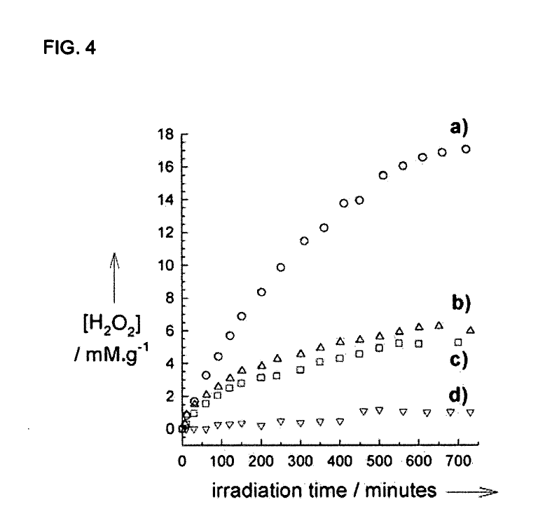

With the morphology-controlled ZnO, we were able to systematically investigate the relationship between crystal growth plane and photocatalytic activity. For this purpose, we monitored the concentration of H₂O₂ formed by a suspension of ZnO crystals under UV irradiation. As shown in FIG. 4, the ZnO nanoplates, with a higher ratio of polar to nonpolar faces, induced rapid generation of H₂O₂, up to 17 mM g⁻¹, under UV irradiation lasting for 730 min. Both the ZnO nanorods and microrods led to the formation of H₂O₂ upon UV irradiation but the formation rate was quite slow compared to that of the nanoplates. Out of both rod-shaped materials, the nanorods, which had a greater surface area of polar faces, showed slightly better activity than the microrods, which is consistent with their respective areas of polar faces (Table 1). This finding is an indication that an increase of polar Zn (0001) or O (0001 ) faces leads to a significant enhancement of photocatalytic activity, whereas the area of nonpolar {011 0} planes has negligible influence on the formation of H₂O₂. However, since the nanoplates possessed both the Zn (0001) and O (0001 ) planes with the same concentration, it was difficult to differentiate which plane was responsible for the photocatalytic activity.

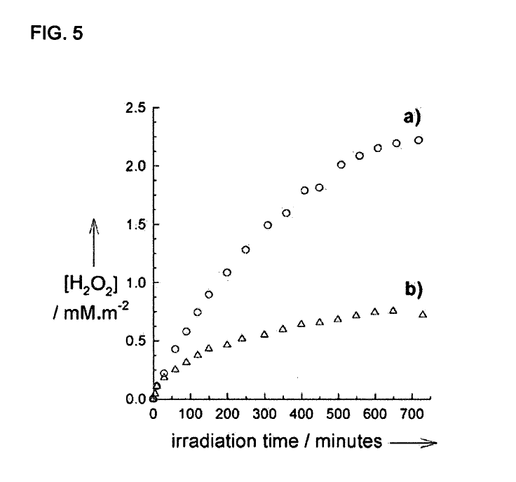

To achieve this differentiation, we also measured the photocatalytic activity of DB microrods with masked Zn (0001) faces. As can be seen clearly in FIG. 5, the H₂O₂ generation caused by the DB microrods was the lowest of all the samples. Although a DB microrod has the smallest surface area among the samples, its photocatalytic activity was even smaller than that of the hexagonal microrod with a similar surface area (Table 1). It is therefore concluded that the polar Zn (0001) plane was the most active site for photocatalytic H₂O₂ generation, even though the photocatalytic activity of the ZnO materials was not strictly quantitatively proportional to the surface area of the Zn (0001) face. This was possibly due to a crude estimation of surface area and/or a broad size distribution of the microcrystalline materials. To confirm this conclusion by ruling out the influence of total surface area on the photocatalytic efficiency, we compared the amount of H₂O₂ evolved after the normalization against the total surface area. As shown in the right panel of FIG. 5, the nanoplates showed better activity than the nanorods, confirming the higher activity of the former morphology. On the other hand, we found that under weak acidic conditions (pH 6.2 at 95° C.), the DB ZnO microrods were changed into plate-shaped crystals due to the sequential dissolution of the polar O (0001 ) faces and the nonpolar {011 0} ones. This result indicated strongly that the Zn (0001) face was more resistant to acidic corrosion than the other faces. Such a difference in the chemical stabilities of the faces would be partially responsible for the higher photocatalytic activity of the ZnO nanoplates, which have a high population of polar Zn (0001) faces.

Having described a preferred embodiment of the present invention, it is to be understood that variants and modifications thereof falling within the spirit of the invention may become apparent to those skilled in this art, and the scope of this invention is to be determined by appended claims and their equivalents.

What is claimed is:

1. A method for increasing a photocatalytic activity of zinc oxide, which comprises preparing zinc oxide nanoplate crystals having a planar morphology on their (0001) crystal faces.

2. The method according to claim 1, wherein the zinc oxide nanoplate crystals have an average thickness of less than 100 nm and an aspect ratio of more than 20.

3. The method according to claim 1, wherein the zinc oxide nanoplate crystals have the (0001) face area of more than 2 m²g⁻¹.

4. A process for synthesizing zinc oxide nanoplate crystals having a planar morphology on their (0001) crystal faces, which comprises inducing a crystal growth of zinc oxide nanoparticles acting as crystal nuclei in a zinc oxide crystal growth solution containing a metal citrate salt.

5. The process according to claim 4, wherein the metal citrate salt is sodium citrate, ammonium citrate or their combination.

6. The process according to claim 4, wherein the zinc oxide crystal growth solution comprises (i) a zinc salt selected from the group consisting of Zn(CH₃COO)₂.(H₂O)ₓ (x is an integer of 0-6), Zn(NO₃)₂.(H₂O)ₓ (x is an integer of 0-6), ZnX₂ (X is F, Cl, Br or I), zinc citrate(H₂O)ₓ (x is an integer of 0-6) and their combination, and (ii) a base selected from the group consisting of sodium hydroxide, lithium hydroxide and their combination.

7. The process according to claim 4, wherein the induction of the crystal growth is carried out for more than 1 hr at 30-400° C.

8. The process according to claim 4, wherein the zinc oxide nanoplate crystals have an average thickness of less than 100 nm and an aspect ratio of more than 20.

9. The process according to claim 4, wherein the zinc oxide nanoplate crystals have the (0001) face area of more than 2 m²g⁻¹.

10. A tooth whitening composition, which comprises an effective amount of zinc oxide nanoplate crystals having a planar morphology on their (0001) crystal faces.

11. The composition according to claim 10, wherein the zinc oxide nanoplate crystals have an average thickness of less than 100 nm and an aspect ratio of more than 20.

12. The composition according to claim 10, wherein the zinc oxide nanoplate crystals have the (0001) face area of more than 2 m²g⁻¹.

13. A composition for degrading organic pollutants, which comprises an effective amount of zinc oxide nanoplate crystals having a planar morphology on their (0001) crystal faces.

14. The composition according to claim 13, wherein the zinc oxide nanoplate crystals have an average thickness of less than 100 nm and an aspect ratio of more than 20.

15. The composition according to claim 13, wherein the zinc oxide nanoplate crystals have the (0001) face area of more than 2 m²g⁻¹.
